(19) United States
(12) Patent Application Publication
(10) Pub. No.: US 2007/0047321 A1
(43) Pub. Date: Mar. 1, 2007

(54) Memory system with two voltage sources

(76) Inventors: Wallace Kou, Los Altos, CA (US); Yu-Wei Chyan, Hsinchu (TW)

Correspondence Address: RABIN & BERDO, P.C.;Suite 500, 1101 14 Street, N.W., Washington, DC, 20005, US

(21) Appl. No.: 11/349,106

(22) Filed: Feb. 8, 2006

(30) Foreign Application Priority Data
Aug. 24, 2005 (TW) 94129000

(51) Int. Cl. G11C 11/34

(52) U.S. Cl. 365/185.23

(57) ABSTRACT

A memory system with two voltage sources comprises a controlling chip which includes a built-in DC/DC converter for transforming low voltage to high voltage, used for transforming 1.8/3.3 voltage to 3.3 voltage. This does not only prevent the phenomenon of voltage drifting but improves the stability of the system.

### RELATED APPLICATIONS

The present application is based on, and claims priority from, Taiwan Application Serial Number 94129000, filed Aug. 24, 2005, the disclosure of which is hereby incorporated by reference herein in its entirety.

### BACKGROUND OF THE INVENTION

1. Field of Invention

The invention relates to a flash memory controlling device and, in particular, to a flash memory controlling device that transforms low voltage to high voltage.

2. Related Art

Since the introduction of flash memory at the end of year 2000, flash memory technology has very wide applications. Devices such as mobile phone, smart phones, personal digital assistants (PDA), and digital cameras have used the flash memory as their storage device. These electronic devices require a huge flash memory to satisfy the market. Therefore, new flash memories are being introduced all the time.

The voltage of the operating environment of current flash memory can be 1.8 V or 3.3 V. To achieve the dual voltage standard, it is conventional to use a high voltage to low voltage stabilizing circuit to covert the 1.8 V or 3.3 V input voltage into a single voltage output of 1.8 V. This power is supplied to the flash memory operating at 1.8 V. Therefore, the memory can function correctly whether it is operating at 1.8 V or 3.3 V.

However, the conventional design has the following serious problems. Since the system voltage input has a certain allowed error range. For example, the allow error range of 1.8 V is from 1.65 V to 1.95 V. The high voltage to low voltage stabilizing circuit has an intrinsic limit; that is, the output voltage is always lower than the input voltage. When the voltage drifting occurs at 1.65 V, the flash memory may only receive 1.62 V. In this case, the entire memory system is unstable. Moreover, for the flash memory whose operating voltage is 3.3 V, the input voltage of the high voltage to low voltage stabilizing circuit has to be greater than 3.3 V. This increases the power consumption.

Therefore, it is desirable to provide a flash memory system to solve the above-mentioned problems.

### SUMMARY OF THE INVENTION

An objective of the invention is to provide a memory system that transforms low voltage to high voltage, thereby increasing the stability of the system and effectively reducing the cost.

Another objective of the invention is to provide a memory controlling chip that can transform low voltage to specific high voltage, providing stable operating voltage for the memory.

In accord with an embodiment of the invention, a low voltage to high voltage stabilizing circuit is built into a memory controlling chip to transform input low voltage to specific high voltage for the operation of the memory.

The disclosed flash memory system includes a memory controlling chip and a flash memory whose operating voltage is 3.3 V. The memory controlling chip includes a built-in DC/DC converter for transforming 1.8/3.3 V to 3.3 V. This does not only improve the stability of the system, but also greatly reduce the system cost.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a diagram of a flash memory system according to the invention.

### DETAILED DESCRIPTION OF THE INVENTION

The present invention will be apparent from the following detailed description, which proceeds with reference to the accompanying drawings, wherein the same references relate to the same elements.

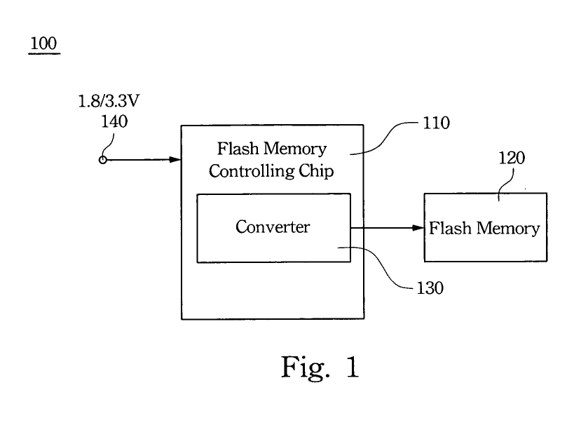

FIG. 1 shows a flash memory system 100 according to a preferred embodiment of the invention. The flash memory system 100 includes a flash memory controller 110 that is built in with a low voltage to high voltage converter 130 and a flash memory 120 whose operating voltage is 3.3 V.

In the disclosed system, a voltage source provides via a system voltage terminal 140 a 1.8/3.3 V operating voltage to the flash memory system 100. The system voltage terminal 140 is coupled to the flash memory controlling chip 110. The flash memory controlling chip 110 is coupled to the flash memory 120 whose operating voltage is 3.3 V. The flash memory controlling chip 110 is built in with a stabilizing circuit 130 for transforming low voltage to high voltage. The stabilizing circuit 130 can be a DC/DC converter. Using the low voltage to high voltage stabilizing circuit 130, the voltage on the system voltage terminal 140 can be converted into 3.3 V for the operation of the flash memory 120.

The low voltage to high voltage stabilizing circuit 130 can readily achieve the conversion of 1.2 V to 3.3 V. In other words, even if the voltage sent from the system voltage terminal 140 is lower than 1.65 V, the low voltage to high voltage stabilizing circuit 130 in the flash memory controlling chip 110 can still convert it and output in 3.3 V for the operation of the flash memory 120.

In summary, the invention has a low voltage to high voltage stabilizing circuit built in a flash memory controlling chip to provide specific voltage for the memory to use. Since it converts low voltage from an input source to high voltage for output, the invention can solve the phenomenon of voltage drifting and system instability in the prior art.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A memory system, comprising:
a memory controlling chip, which includes at least a low voltage to high voltage stabilizing circuit for transforming low voltage to high voltage; and
a memory, which is coupled to the memory controlling chip and is operating at high voltage.

2. The system of claim 1, wherein the memory is a flash memory.

3. The system of claim 1, wherein the input low voltage is 1.8 V.

4. The system of claim 1, wherein the input low voltage is 3.3 V.

5. The system of claim 1, wherein the output high voltage is 3.3 V.

6. The system of claim 1, wherein the low voltage to high voltage stabilizing circuit is a DC/DC converter.

7. A memory controlling device for providing voltage to a memory, comprising: a stabilizing circuit for transforming low voltage to high voltage to be supplied to the memory.

8. The device of claim 7, wherein the input low voltage is 1.8 V.

9. The device of claim 7, wherein the input low voltage is 3.3 V.

10. The device of claim 7, wherein the output high voltage is 3.3 V.

11. The device of claim 7, wherein the memory is a flash memory.

12. The device of claim 7, wherein the stabilizing circuit is a DC/DC converter.
